(19) United States
(12) Patent Application Publication
(10) Pub. No.: US 2025/0048608 A1
(43) Pub. Date: Feb. 6, 2025

(54) SUBSTRATE MANUFACTURING METHOD AND COMPONENT MOUNTING MACHINE

(71) Applicant: FUJI CORPORATION, Chiryu (JP)

(72) Inventors: Yuki HINO, Mihama-cho, Chita-gun (JP); Tetsuya FUKAGAWA, Toyohashi-shi (JP); Akihiro SENGA, Okazaki-shi (JP)

(73) Assignee: FUJI CORPORATION, Chiryu (JP)

(21) Appl. No.: 18/718,072

(22) PCT Filed: Jan. 25, 2022
(86) PCT No.: PCT/JP2022/002542

§ 371 Date: Jun. 10, 2024

(51) Int. Cl. H05K 13/04

(52) U.S. Cl. CPC H05K 13/0408

(57) ABSTRACT

A substrate manufacturing method is a method for manufacturing a substrate on which multiple components are mounted. In this method, some components among the multiple components are mounted via a first operation of lowering the collecting member until contact of the component with the substrate is detected by a contact detection sensor, and of measuring a contact height in a mounting position of the component based on the detection of the contact performed by the contact detection sensor. In addition, other components are mounted via a second operation of setting a target height based on a measurement result of the contact height when the some components are mounted via the first operation, and of lowering the collecting member until the component is positioned at the target height.

### TECHNICAL FIELD

The present description discloses a substrate manufacturing method and a component mounting machine.

### BACKGROUND ART

Conventionally, as a component mounting machine of this type, there has been proposed a component mounting machine that measures substrate heights in multiple measurement regions using a height sensor, derives a representative value of the substrate height in each of the multiple measurement regions to acquire warpage data of the substrate, corrects a mounting height based on the warpage data, and mounts a component on the substrate (for example, refer to Patent Literatures 1 and 2). In this component mounting machine, the substrate height measurement using the height sensor is executed by selecting whether to execute multiple-point height measurement processing of measuring multiple measurement points in a measurement region or single-point height measurement processing of measuring one measurement point in a measurement region for each type of the substrate on which a component is mounted. Accordingly, it is possible to shorten a time for measuring the substrate height when the single-point height measurement is used.

### PATENT LITERATURE

Patent Literature 1: JP-A-2017-152453
Patent Literature 2: JP-A-2017-152454

### BRIEF SUMMARY

### Technical Problem

However, in the component mounting machine described above, depending on the type of the substrate, the number of measurement points increases because of the multiple-point height measurement, and thus the time for measuring becomes long, and the production efficiency deteriorates.

A main object of the present disclosure is to mount a component with good accuracy and to suppress an increase in the number of measurement points for a height of a substrate regardless of a type of the substrate even when the substrate is warped.

### Solution to Problem

The present disclosure employs the following means in order to achieve the main object described above.

A substrate manufacturing method of the present disclosure is
a method for manufacturing a substrate on which multiple components are mounted by causing a collecting member to collect a component and then lowering the collecting member to mount the component collected by the collecting member on the substrate, the substrate manufacturing method including:
mounting some components among the multiple components via a first operation of lowering the collecting member until contact of the component with the substrate is detected by a contact detection sensor, and of measuring a contact height in a mounting position of the component based on the detection of the contact performed by the contact detection sensor, and mounting other components via a second operation of setting a target height based on a measurement result of the contact height when the some components are mounted via the first operation, and of lowering the collecting member until the component is positioned at the target height.

In the substrate manufacturing method of the present disclosure, the target height is set in the second operation based on the measurement result of the contact height measured in the first operation, so that it is possible to mount the component with good accuracy even when the substrate is warped.

Also in the component mounting machine of the present disclosure, the same effect as that of the substrate manufacturing method of the present disclosure can be achieved.

### BRIEF DESCRIPTION OF DRAWINGS

FIG. 1 is a schematic configuration diagram of a component mounting machine according to the present embodiment.

FIG. 2 is a schematic configuration diagram of a head.

FIG. 3 is a schematic configuration diagram of a holder.

FIG. 4 is a diagram showing electric connections of the component mounting machine.

FIG. 5 is a flowchart showing an example of mounting processing.

FIG. 6 is a diagram showing a mounting position of a mounting target component and a range in which the mounting target component can be mounted in a normal operation.

FIG. 7A is a diagram showing how a nozzle height changes with time during a searching operation.

FIG. 7B is a diagram showing how the nozzle height changes with time in the normal operation.

FIG. 8 is a diagram showing the mounting position of the mounting target component and a range in which the mounting target component can be mounted in the normal operation.

### DESCRIPTION OF EMBODIMENTS

Next, an embodiment of the present disclosure will be described with reference to the drawings.

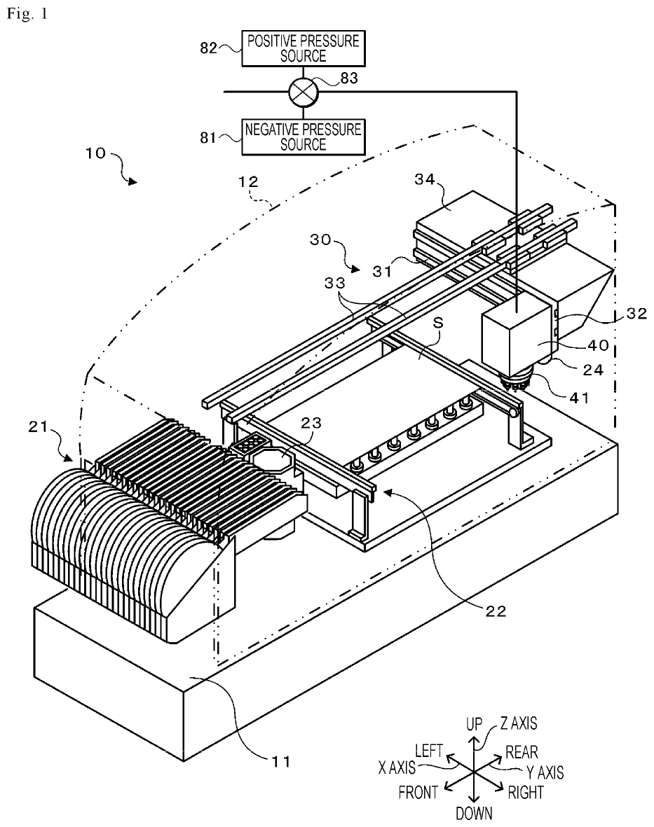

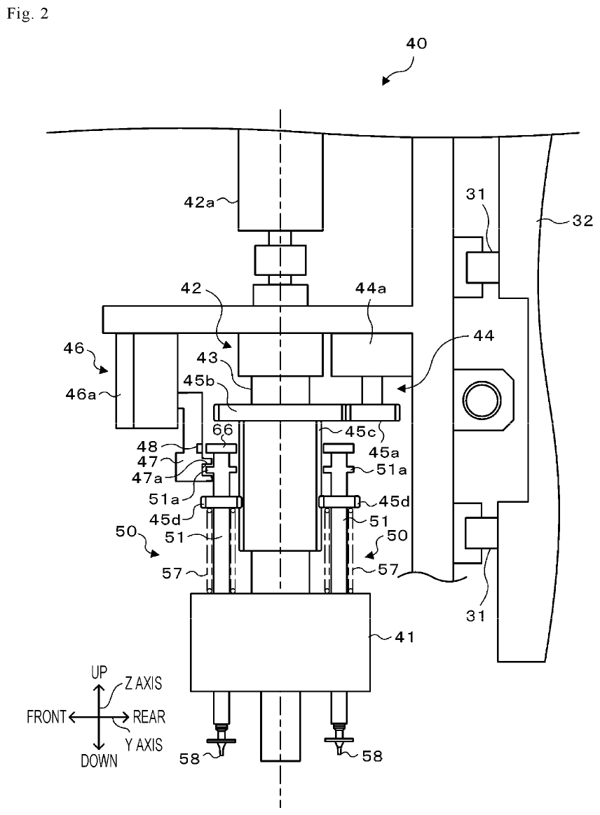

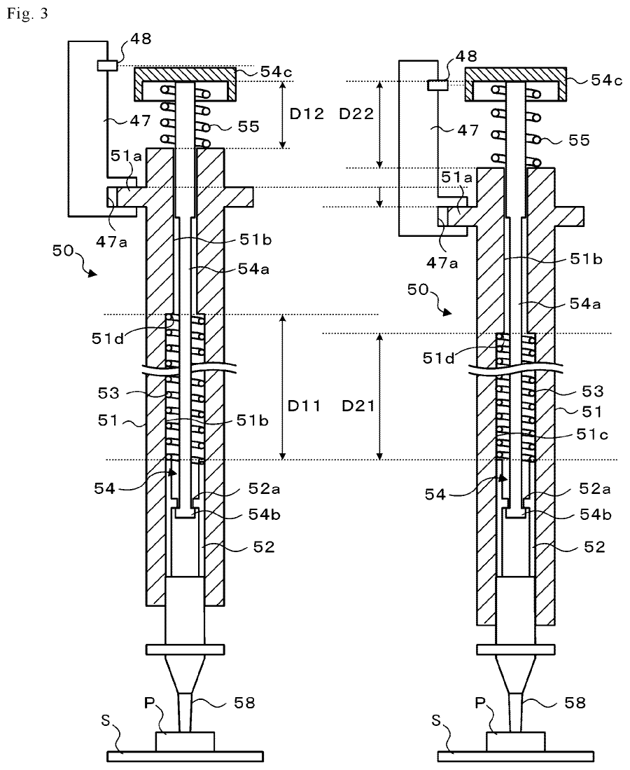

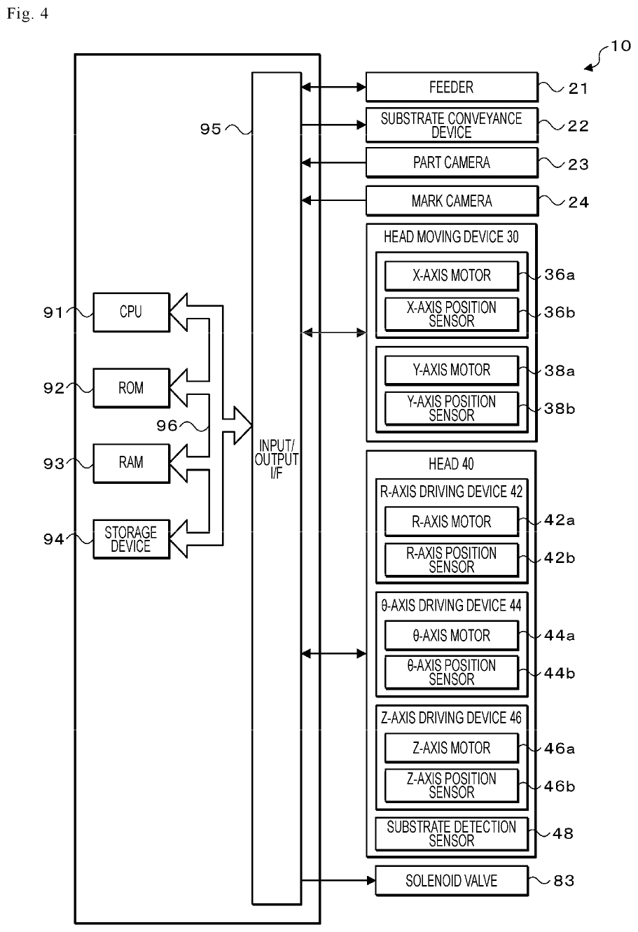

FIG. 1 is a schematic configuration diagram of component mounting machine 10 according to the present embodiment. FIG. 2 is a schematic configuration diagram of head 40. FIG. 3 is a schematic configuration diagram of holder 50. FIG. 4 is a diagram showing electric connections of component mounting machine 10. In FIG. 1, a left-right direction indicates an X-axis direction, a front (near side)-rear (far side) direction indicates a Y-axis direction, and an up-down direction indicates a Z-axis direction.

Component mounting machine 10 of the present embodiment produces substrate S on which multiple components are mounted, and multiple component mounting machines 10 are arranged along a substrate conveyance direction to configure a production line. As shown in FIG. 1, component mounting machine 10 includes base 11 and module 12 installed on base 11. Module 12 configures a mounting machine main body, and includes feeder 21, substrate conveyance device 22, head 40, and head moving device 30.

Feeder 21 is detachably attached to a feeder base (not shown) installed in a front portion of component mounting machine 10. Feeder 21 is, for example, a tape feeder and includes a carrier tape in which components are respectively accommodated in multiple cavities formed at predetermined intervals, a reel around which the carrier tape is wound, and a tape feeding device that unwinds and feeds the carrier tape from the reel.

Substrate conveyance device 22 is a belt conveyor device that conveys substrate S to the left and right (X-axis direction) with a conveyor belt. Substrate conveyance device 22 includes a pair of front and rear conveyor belts each of which is stretched over a pair of rollers and is disposed at a predetermined interval in the front and rear (Y-axis direction), and a belt driving device that drives the conveyor belts to rotate. At least a first one of the pair of conveyor belts is configured to approach and separate from a second one thereof. Accordingly, substrate conveyance device 22 can convey multiple types of substrates S having different widths in the Y-axis direction by adjusting the interval between the pair of conveyor belts in the Y-axis direction.

As shown in FIG. 1, head moving device 30 includes X-axis guide rail 31, X-axis slider 32, Y-axis guide rails 33, and Y-axis slider 34. Y-axis guide rails 33 are provided in a pair on the left and right along the front-rear direction (Y-axis direction) in an upper step portion of module 12. Y-axis slider 34 is stretched over the pair of left and right Y-axis guide rails 33, and moves back and forth (Y-axis direction) by being driven by Y-axis motor 38a (refer to FIG. 4). X-axis guide rail 31 is provided on a front surface of Y-axis slider 34 along the left-right direction (X-axis direction). X-axis slider 32 moves to the left and right (X-axis direction) by being driven by X-axis motor 36a (refer to FIG. 4). Head 40 is attached to X-axis slider 32. Therefore, head 40 is movable forward, backward, leftward, and rightward via head moving device 30 (X-axis motor 36a and Y-axis motor 38a). Head moving device 30 is provided with X-axis position sensor 36b (refer to FIG. 4) for detecting a position of X-axis slider 32 in the X-axis direction and Y-axis position sensor 38b (refer to FIG. 4) for detecting a position of Y-axis slider 34 in the Y-axis direction.

In the present embodiment, head 40 is configured as a rotary head. As shown in FIG. 2, head 40 includes rotating body 41, multiple holders 50 arranged on rotating body 41 at predetermined angular intervals in a circumferential direction, and suction nozzles 58 detachably attached to respective holders 50. Head 40 further includes R-axis driving device 42, θ-axis driving device 44, and Z-axis driving device 46.

Any of negative pressure source 81 such as a vacuum pump, positive pressure source 82 such as a compressor, and an atmospheric air introduction inlet is selectively connected to suction nozzle 58 attached to each holder 50 via solenoid valve 83. By operating solenoid valve 83 such that suction nozzle 58 is connected to negative pressure source 81, a negative pressure can be supplied to suction nozzle 58 to pick up the component with suction nozzle 58. Further, by operating solenoid valve 83 such that suction nozzle 58 is connected to positive pressure source 82, component picked up by suction nozzle 58 can be mounted on substrate S.

R-axis driving device 42 causes multiple holders 50 to revolve in the circumferential direction. R-axis driving device 42 includes R-axis motor 42a and shaft portion 43 that is connected to a rotation shaft of R-axis motor 42a and is coaxially connected to rotating body 41. R-axis driving device 42 causes multiple holders 50 arranged on rotating body 41 to revolve in the circumferential direction by rotationally driving rotating body 41 with R-axis motor 42a. R-axis driving device 42 is provided with R-axis position sensor 42b for detecting a rotational position of rotating body 41.

θ-axis driving device 44 causes multiple holders 50 to rotate (revolve). θ-axis driving device 44 includes θ-axis motor 44a and transmission gears 45a to 45d that transmit rotation of θ-axis motor 44a to respective holders 50. Transmission gear 45c is an external spur gear that is arranged on a concentric circle with shaft portion 43 and can relatively rotate with respect to shaft portion 43, and is connected to a rotation shaft of θ-axis motor 44a via transmission gears 45a and 45b. In addition, transmission gears 45d are external spur gears which are coaxially provided in respective holders 50 and of which each is meshed with transmission gear 45c. Transmission gear 45c vertically extends, and holder 50 is vertically slidable in a state where the meshing of transmission gears 45c and 45d is maintained. θ-axis driving device 44 causes each holder 50 to rotate at a certain angle by rotationally driving each holder 50 with θ-axis motor 44a via transmission gears 45a to 45d. θ-axis driving device 44 is provided with θ-axis position sensor 44b for detecting a rotational position of each holder 50.

Z-axis driving device 46 vertically (Z-axis direction) moves (lifts and lowers) holder 50 at a predetermined revolving position among multiple holders 50 held in rotating body 41. Z-axis driving device 46 includes Z-axis motor 46a and Z-axis slider 47 that is lifted and lowered by Z-axis motor 46a. Z-axis slider 47 includes engagement groove 47a engaged with engagement piece 51a of holder 50 at the predetermined revolving position. Z-axis driving device 46 lowers holder 50 engaged with Z-axis slider 47 by lowering Z-axis slider 47 with Z-axis motor 46a. Z-axis driving device 46 is provided with Z-axis position sensor 46b for detecting a lifting/lowering position of Z-axis slider 47 (holder 50).

As shown in FIG. 3, holder 50 includes syringe 51, first displacement member 52, first spring 53, second displacement member 54, and second spring 55. Suction nozzle 58 is detachably attached to a lower end portion of syringe 51. On an upper portion of syringe 51, engagement piece 51a protruding outward in a radial direction is provided. When holder 50 revolves to the predetermined revolving position, engagement piece 51a is engaged with engagement groove 47a of Z-axis slider 47. Z-axis slider 47 is lowered in a state where engagement piece 51a is engaged with engagement groove 47a, so that holder 50 is pushed down by Z-axis slider 47 and lowered. Further, spring 57 is disposed between transmission gear 45d and rotating body 41, and when Z-axis slider 47 is lifted, holder 50 is lifted by being biased by a biasing force of spring 57.

An inner peripheral surface of syringe 51 includes small-diameter inner peripheral portion 51b formed on an upper side, large-diameter inner peripheral portion 51c formed on a lower side with an inner diameter larger than that of small-diameter inner peripheral portion 51b, and step portion 51d formed at a boundary portion between small-diameter inner peripheral portion 51b and large-diameter inner peripheral portion 51c.

First displacement member 52 is a cylindrical member accommodated in large-diameter inner peripheral portion 51c of syringe 51 so as to be vertically displaceable with respect to syringe 51. A lower end portion of first displacement member 52 is in contact with an upper end portion of suction nozzle 58. First spring 53 is accommodated in a compressed state between an upper end portion of first displacement member 52 on large-diameter inner peripheral portion 51c and step portion 51d of syringe 51. First displacement member 52 is biased downward with respect to syringe 51 by a biasing force of first spring 53. Suction nozzle 58 is biased downward by the biasing force of first spring 53 via first displacement member 52. When suction nozzle 58 is pushed up, suction nozzle 58 and first displacement member 52 are displaced upward with respect to syringe 51 with contraction of first spring 53.

Second displacement member 54 is a rod-shaped member inserted into syringe 51. Second displacement member 54 includes shaft portion 54a, engagement portion 54b provided at a lower end portion of shaft portion 54a, and detected portion 54c provided at an upper end portion of shaft portion 54a.

Engagement portion 54b has an outer diameter larger than an outer diameter of shaft portion 54a and smaller than an inner diameter of first displacement member 52 so as to be insertable into first displacement member 52. On an inner peripheral surface of first displacement member 52, annular restricting portion 52a protruding inward in the radial direction is provided. Restricting portion 52a has an inner diameter larger than the outer diameter of shaft portion 54a and smaller than an outer diameter of engagement portion 54b. Shaft portion 54a is inserted into an opening of restricting portion 52a, and engagement portion 54b is positioned below restricting portion 52a.

Detected portion 54c is a disc-shaped member having an outer diameter larger than the inner diameter of small-diameter inner peripheral portion 51b of syringe 51. Second spring 55 is disposed in a compressed state between an upper end surface of syringe 51 and a lower end surface of detected portion 54c. Engagement portion 54b is engaged with restricting portion 52a by an upward biasing force of second spring 55, and second displacement member 54 is positioned with respect to first displacement member 52. Meanwhile, the upward biasing force of second spring 55 is set to be smaller than the downward biasing force of first spring 53. Therefore, second displacement member 54 is biased downward.

An operation of holder 50 configured as above will be described with reference to FIG. 3. A left side of FIG. 3 shows a state immediately before component P picked up by suction nozzle 58 comes into contact with substrate S. In this state, a length of first spring 53 is defined as D11, and a length of second spring 55 is defined as D12. Before component P comes into contact with substrate S, syringe 51, first displacement member 52, second displacement member 54, and suction nozzle 58 are integrally lowered by the lowering of Z-axis slider 47.

A right side of FIG. 3 shows a state in which component P picked up by suction nozzle 58 comes into contact with substrate S and is slightly pushed in. In this state, the length of first spring 53 is D21, and the length of second spring 55 is D22. When component P picked up by suction nozzle 58 comes into contact with substrate S and component P is further pushed into substrate S via the lowering of Z-axis slider 47, suction nozzle 58 and first displacement member 52 are displaced relatively upward with respect to syringe 51. In this case, since first spring 53 is compressed, length D21 of first spring 53 is shorter than length D11 before the contact. Meanwhile, since second displacement member 54 is biased upward with respect to syringe 51 by second spring 55, second displacement member 54 is displaced upward with respect to syringe 51 while engagement portion 54b is engaged with restricting portion 52a in accordance with the upward displacement of first displacement member 52. In this case, since second spring 55 is stretched, length D22 of second spring 55 is longer than length D21 before the contact. Accordingly, since detected portion 54c is displaced relatively upward with respect to substrate detection sensor 48 that is displaced integrally with syringe 51 as Z-axis slider 47 is lowered, the contact of component P with substrate S is detected by substrate detection sensor 48.

Module 12 also includes part camera 23, mark camera 24, and the like. Part camera 23 captures an image of component P picked up by suction nozzle 58 from below in order to check a posture or the like of component P. Mark camera 24 captures an image of a mark attached to substrate S from above in order to check a position of substrate S.

As shown in FIG. 4, control device 90 includes CPU 91, ROM 92, RAM 93, storage device 94 such as a hard disk or an SSD, and input/output interface 95. These sections are electrically connected with one another via bus 96. Various signals from part camera 23, mark camera 24, X-axis position sensor 36b, Y-axis position sensor 38b, R-axis position sensor 42b, θ-axis position sensor 44b, Z-axis position sensor 46b, and the like are input to control device 90 via input/output interface 95. Meanwhile, drive signals to feeder 21, substrate conveyance device 22, head moving device 30 (X-axis motor 36a and Y-axis motor 38a), head 40 (R-axis motor 42a, θ-axis motor 44a, Z-axis motor 46a, and the like), and the like are output from control device 90 via input/output interface 95.

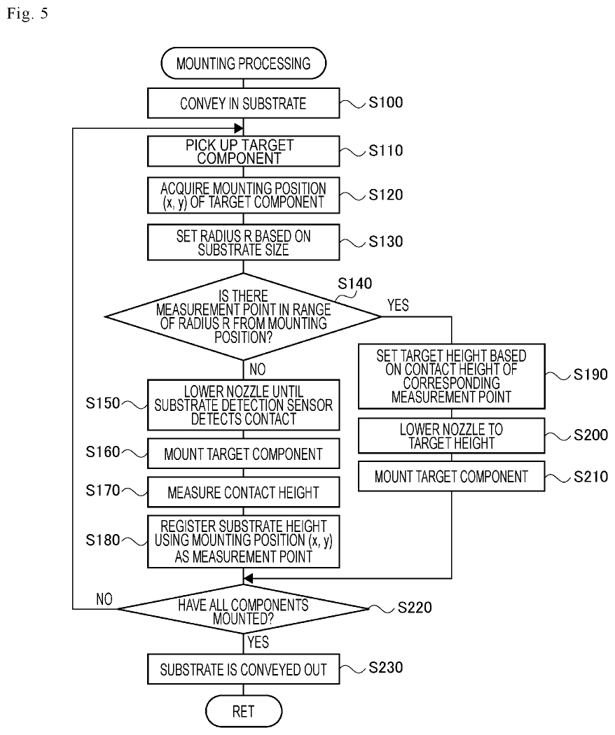

Next, an operation of component mounting machine 10 configured as above will be described. FIG. 5 is a flowchart showing an example of mounting processing executed by CPU 91 of control device 90. This processing is executed when a production job is received from a management device (not shown). The production job includes a type and a size of substrate S to be produced and a type and a mounting position of a component to be mounted on substrate S.

When the mounting processing is executed, CPU 91 of control device 90 first controls substrate conveyance device 22 such that substrate S is conveyed in (step S100). Subsequently, CPU 91 performs a pickup operation of picking up the component (mounting target component) supplied from feeder 21 to a component supply position (step S110). The pickup operation is performed as follows. That is, CPU 91 controls head moving device 30 and R-axis motor 42a such that a position in an XY-axis direction of suction nozzle 58, which is at a revolving position in which suction nozzle 58 can be lowered, among multiple suction nozzles 58 of head 40 matches XY coordinates of the component supply position. Then, CPU 91 controls the driving of Z-axis driving device 46 (Z-axis motor 46a) such that the lowering of suction nozzle 58 is started, and controls solenoid valve 83 such that the negative pressure is supplied to lowered suction nozzle 58. When the mounting target component is picked up by suction nozzle 58, CPU 91 moves a pickup target component above part camera 23, and captures an image of the pickup target component with part camera 23. Then, CPU 91 processes the captured image to measure a pickup deviation amount of the pickup target component.

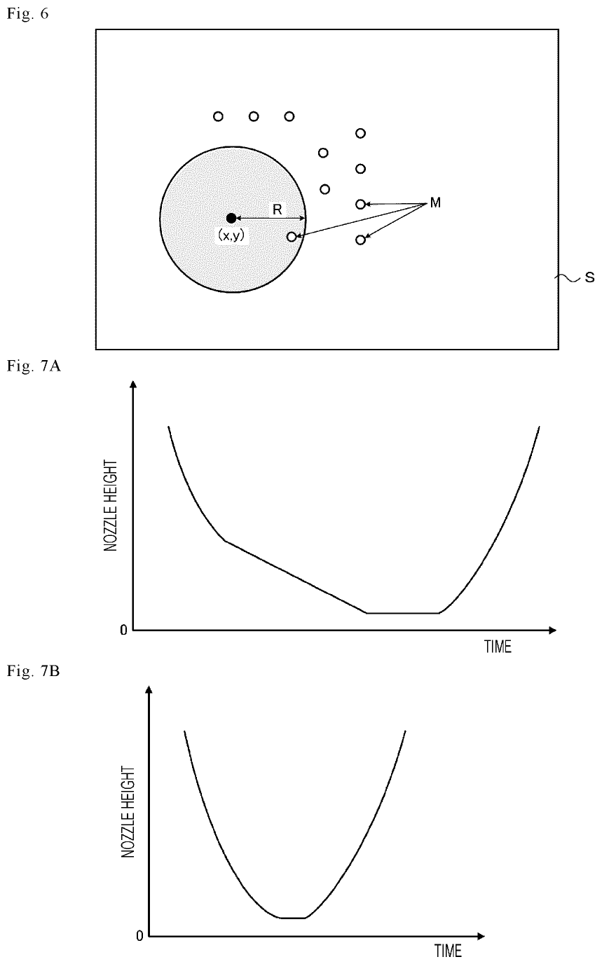

Next, CPU 91 acquires a mounting position (x, y) of the mounting target component (step S120). Subsequently, CPU 91 sets radius R based on the size of substrate S being produced included in the production job (step S130), and determines whether there is a measurement point described later within a range of radius R based on the mounting position (x, y) of the mounting target component (step S140). In this determination, as shown in FIG. 6, it is determined whether the mounting position (x, y) of the mounting target component is in the vicinity of a mounted component which is mounted on substrate S and whose height has been measured during mounting via a searching operation described later. In the present embodiment, radius R is set to decrease as the size (width) of substrate S increases. The size of substrate S can be acquired based on information input by an operator.

When it is determined that there is no measurement point within the range of radius R from the mounting position (x, y) of the mounting target component, CPU 91 performs the searching operation of lowering suction nozzle 58 that has picked up the mounting target component until substrate detection sensor 48 detects the contact of the mounting target component with substrate S (step S150). Specifically, the searching operation is performed as follows. That is, CPU 91 controls head moving device 30 and R-axis motor 42a such that suction nozzle 58, which has picked up the mounting target component, among multiple suction nozzles 58 of head 40 is positioned at a revolving position in which suction nozzle 58 can be lowered, and the mounting target component is positioned above the mounting position (x,y). The mounting position (x,y) is corrected based on the pickup deviation amount of the mounting target component. Subsequently, CPU 91 controls Z-axis motor 46a such that suction nozzle 58 that has picked up the mounting target component is lowered. Here, as shown in FIG. 7A, the lowering of suction nozzle 58 is performed such that suction nozzle 58 moves at a relatively low speed to such an extent that a large impact is not applied to the component or substrate S when the mounting target component comes into contact with substrate S. Then, when the contact of the mounting target component with substrate S is detected by substrate detection sensor 48, CPU 91 controls solenoid valve 83 such that a positive pressure is supplied to suction nozzle 58 that has picked up the mounting target component, and mounts the mounting target component at the mounting position (x,y) of substrate S (step S160). An operation timing of solenoid valve 83 in the searching operation is a timing at which the contact of the mounting target component with substrate S is detected by substrate detection sensor 48.

When the mounting target component is mounted on substrate S via the searching operation, CPU 91 measures a height (contact height) of suction nozzle 58 when the mounting target component comes into contact with substrate S based on the signal detected by Z-axis position sensor 46b (step S170), and registers the measured contact height in storage device 94 using the mounting position (x, y) of the mounting target component as a measurement point (step S180). Accordingly, in processing of step S140 in future repetitions, CPU 91 determines whether any of the measurement points registered in storage device 94 is within the range of radius R from the mounting position (x, y) of the mounting target component.

Then, CPU 91 determines whether mounting of all the components scheduled for substrate S has been completed (step S220). When it is determined that the mounting of all the scheduled components is not completed, CPU 91 returns to step S110 and repeats the mounting processing with the remaining components as the mounting target components.

When it is determined in step S140 that the measurement point is within the range of radius R from the mounting position (x, y) of the mounting target component, CPU 91 sets the contact height of the corresponding measurement point as a target height (step S190). Subsequently, CPU 91 performs a normal operation of lowering suction nozzle 58 to the target height (step S200). The normal operation is specifically performed as follows. That is, CPU 91 controls head moving device 30 and R-axis motor 42a such that suction nozzle 58, which has picked up the mounting target component, among multiple suction nozzles 58 of head 40 is positioned at a revolving position in which suction nozzle 58 can be lowered, and the mounting target component is positioned above the mounting position (x,y). The mounting position (x,y) is corrected based on the pickup deviation amount of the mounting target component. Subsequently, CPU 91 controls Z-axis motor 46a such that suction nozzle 58 is lowered to the target height. Here, as shown in FIG. 7B, the lowering of suction nozzle 58 is performed such that suction nozzle 58 moves at a relatively high speed via feedback control based on the height of suction nozzle 58 calculated based on the signal detected by Z-axis position sensor 46b and on the target height. Accordingly, it is possible to quickly lower the mounting target component to substrate S compared to the searching operation, and it is possible to shorten a time required for mounting the mounting target component. Then, CPU 91 controls solenoid valve 83 such that the positive pressure is supplied to suction nozzle 58 that has picked up the mounting target component, and mounts the mounting target component at the mounting position (x,y) of substrate S (step S210). In the present embodiment, an operation timing of solenoid valve 83 in the normal operation is a timing at which suction nozzle 58 is lowered to a position a predetermined distance before the target height in consideration of a time lag from the start of the operation of solenoid valve 83 to the actual supply of the positive pressure to suction nozzle 58. Accordingly, it is possible to supply the positive pressure to suction nozzle 58 substantially at the same time as the mounting target component comes into contact with substrate S, and it is possible to shorten the time required for mounting the mounting target component compared to the searching operation.

When it is determined in step S220 that the mounting of all the components scheduled for substrate S has been completed, CPU 91 controls substrate conveyance device 22 such that substrate S is conveyed out (step S230), and ends the mounting processing.

Here, a correspondence relationship between the elements of the present embodiment and the elements of the present disclosure will be clarified. Suction nozzle 58 of the present embodiment corresponds to a collecting member of the present disclosure, and substrate detection sensor 48 corresponds to a contact detection sensor. Head 40 corresponds to a head, head moving device 30 corresponds to a moving device, Z-axis driving device 46 corresponds to a lifting and lowering device, and control device 90 corresponds to a control section.

The present disclosure is not limited in any way to the embodiment described above, and it is needless to say that the present disclosure can be achieved in various forms as long as they belong to the technical scope of the present disclosure.

For example, in the embodiment described above, CPU 91 sets, based on the size of substrate S, the vicinity range (radius R) used for determining whether there is the measurement point in the vicinity of the mounting position (x, y) of the mounting target component. However, the vicinity range (radius R) may be set in accordance with the maximum warpage amount of substrate S, the type of substrate S, and the lot, which are registered in advance via input of the operator or the like, or may be set to a constant value.

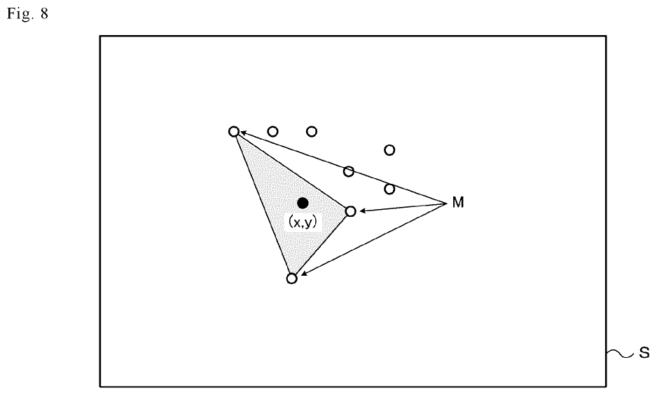

In the embodiment described above, CPU 91 determines whether there is the measurement point at which the contact height has been measured in the vicinity of the mounting position (x, y) of the mounting target component, sets the contact height measured at the corresponding measurement point as the target height, and performs the normal operation. However, CPU 91 may determine whether there are multiple measurement points in the vicinity of the mounting position (x, y) of the mounting target component, set the target height based on the multiple corresponding measurement points using an interpolation method, and perform the normal operation. Any method may be adopted as the interpolation method, however, for example, as shown in FIG. 8, CPU 91 may determine whether the mounting position (x, y) of the mounting target component is within a vicinity range surrounded by multiple (three) measurement points, and set the target height based on the contact heights in the multiple measurement points via a surface interpolation method when it is determined that the mounting position is within the vicinity range.

Further, CPU 91 may execute the searching operation to measure the contact height at the mounting position of each component and register the measured contact height in storage device 94 until a predetermined number of measurement points are obtained, create warpage data of the entire substrate based on the measurement points when the predetermined number of measurement points are obtained, and thereafter perform the normal operation by setting the target height based on the mounting position (x,y) based on the created warpage data.

As described above, in the substrate manufacturing method of the present disclosure, the target height is set in the second operation (normal operation) based on the measurement result of the contact height measured along with the mounting of the component in the first operation (searching operation), so that it is possible to mount the component with good accuracy even when the substrate is warped. In addition, it is possible to further shorten the mounting time compared to a case where all the components are mounted via the first operation.

In the substrate manufacturing method of the present disclosure, when a mounting position of a mounting target component is not within a predetermined range from the mounting position of the component mounted via the first operation, the mounting target component may be mounted via the first operation, and, when the mounting position of the mounting target component is within the predetermined range, the mounting target component may be mounted via the second operation. It is possible to mount the component via the second operation as much as possible while ensuring the mounting accuracy of the component, and it is possible to further shorten the mounting time.

In the substrate manufacturing method of the present disclosure, the predetermined range may be set based on at least any one of a size and a maximum warpage amount of the substrate, which are registered in advance. This makes it possible to more appropriately set the predetermined range according to the substrate.

In addition, the present disclosure is not limited to a form of a substrate manufacturing method, and may be a form of a component mounting machine.

### INDUSTRIAL APPLICABILITY

The present disclosure can be applied in the manufacturing industry for the component mounting machine and the like.

### REFERENCE SIGNS LIST

10 component mounting machine, 11 base, 12 module, 21 feeder, 22 substrate conveyance device, 23 part camera, 24 mark camera, 30 head moving device, 31 X-axis guide rail, 32 X-axis slider, 33 Y-axis guide rail, 34 Y-axis slider, 36a X-axis motor, 36b X-axis position sensor, 38a Y-axis motor, 38b Y-axis position sensor, 40 head, 41 rotating body, 42 R-axis driving device, 42a R-axis motor, 42b R-axis position sensor, 43 shaft portion, 44 θ-axis driving device, 44a θ-axis motor, 44b θ-axis position sensor, 45a to 45d transmission gear, 46 Z-axis driving device, 46a Z-axis motor, 46b Z-axis position sensor, 47 Z-axis slider, 47a engagement groove, 48 substrate detection sensor, 50 holder, 51 syringe, 51a engagement piece, 51b small-diameter inner peripheral portion, 51c large-diameter inner peripheral portion, 51d step portion, 52 first displacement member, 52a restricting portion, 53 first spring, 54 second displacement member, 54a shaft portion, 54b engagement portion, 54c detected portion, 55 second spring, 57 spring, 58 suction nozzle, 81 negative pressure source, 82 positive pressure source, 83 solenoid valve, 90 control device, 91 CPU, 92 ROM, 93 RAM, 94 storage device, 95 input/output interface, 96 bus, P component, R radius, S substrate

1. A substrate manufacturing method for manufacturing a substrate on which multiple components are mounted by causing a collecting member to collect a component and then lowering the collecting member to mount the component collected by the collecting member on the substrate, the substrate manufacturing method comprising:
mounting some components among the multiple components via a first operation of lowering the collecting member until contact of the component with the substrate is detected by a contact detection sensor, and of measuring a contact height in a mounting position of the component based on the detection of the contact performed by the contact detection sensor, and mounting other components via a second operation of setting a target height based on a measurement result of the contact height when the some components are mounted via the first operation, and of lowering the collecting member until the component is positioned at the target height.

2. The substrate manufacturing method according to claim 1, further comprising:
mounting, when a mounting position of a mounting target component is not within a predetermined range from the mounting position of the component mounted via the first operation, the mounting target component via the first operation, and mounting, when the mounting position of the mounting target component is within the predetermined range, the mounting target component via the second operation.

3. The substrate manufacturing method according to claim 1,
wherein the predetermined range is set based on at least any one of a size and a maximum warpage amount of the substrate, which are registered in advance.

4. A component mounting machine for collecting a component and mounting the component on a substrate, the component mounting machine comprising:
a head configured to hold a collecting member configured to collect the component;
a moving device configured to relatively move the head with respect to the substrate;
a lifting and lowering device configured to lift and lower the collecting member with respect to the head;
a contact detection sensor configured to detect contact of the component collected by the collecting member with the substrate; and
a control section configured to control the head, the moving device, and the lifting and lowering device such that multiple components are respectively mounted at corresponding mounting positions in a mounting order set in advance with respect to the substrate, mount some components among the multiple components via a first operation of lowering the collecting member until the contact of the component with the substrate is detected by the contact detection sensor, and of measuring a contact height in a mounting position of the component based on the detection of the contact performed by the contact detection sensor, and mount other components via a second operation of setting a target height based on a measurement result of the contact height when the some components are mounted via the first operation, and of lowering the collecting member until the component is positioned at the target height.
